(19) United States
(12) Patent Application Publication
(10) Pub. No.: US 2024/0268083 A1
(43) Pub. Date: Aug. 8, 2024

(54) REFRIGERATION AIR WALL APPARATUS AND DATA CENTER

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Shuqin FENG, Zhangjiakou City (CN)

(21) Appl. No.: 18/420,991

(22) Filed: Jan. 24, 2024

(30) Foreign Application Priority Data
Feb. 6, 2023 (CN) 202310080273.0

(51) Int. Cl. H05K 7/20

(52) U.S. Cl. CPC H05K 7/20745; H05K 7/20836

(57) ABSTRACT

The present disclosure discloses a refrigeration air wall apparatus and a data center. The refrigeration air wall apparatus at least includes a heat exchange unit, a dehumidification unit, and a fan unit. The dehumidification unit is positioned between the heat exchange unit and the fan unit along an air flow direction, and the dehumidification unit is positioned in front of the heat exchange unit. The dehumidification unit includes a first gas-to-liquid heat exchanger, a first liquid-to-liquid heat exchanger, and a first electric valve. The first gas-to-liquid heat exchanger is connected in series with an internal channel of the first liquid-to-liquid heat exchanger to form an internal circulation loop, and the first electric valve is connected in series with the internal circulation loop. An external channel of the first liquid-to-liquid heat exchanger is connected in series with a first external cold source device to form an external circulation loop.

### CROSS-REFERENCE TO RELATED APPLICATION

This application claims priority to Chinese patent application Ser. No. 202310080273.0, titled “REFRIGERATION AIR WALL APPARATUS AND DATA CENTER” and filed to the China National Intellectual Property Administration on Feb. 6, 2023, the entire contents of which are incorporated herein by reference.

### TECHNICAL FIELD

The present disclosure relates to the field of refrigeration equipment, and more particularly, to a refrigeration air wall apparatus and a data center.

### BACKGROUND

In data centers, generally refrigeration systems comprised of refrigeration air wall apparatuses are employed to cool and supply air to devices such as servers in the data centers to take away heat generated during operation.

The existing refrigeration air wall apparatuses can only meet requirements for temperature of the data centers, but cannot simultaneously meet requirements for humidity of the data centers.

In the existing data centers, to solve the humidity problem of the data centers, it is generally needed to separately provide dehumidifiers and humidifiers in the data centers, which leads to more systems in the data centers, complex system architecture, complicated on-site construction, and increased initial investment.

### SUMMARY

Objectives of the present disclosure are to provide a refrigeration air wall apparatus and a data center to simplify a system architecture.

In one aspect, the present disclosure provides a refrigeration air wall apparatus, which at least includes a heat exchange unit, a dehumidification unit, and a fan unit. The dehumidification unit is positioned between the heat exchange unit and the fan unit along an air flow direction, and the dehumidification unit is positioned in front of the heat exchange unit. The dehumidification unit includes a first gas-to-liquid heat exchanger, a first liquid-to-liquid heat exchanger, and a first electric valve. The first gas-to-liquid heat exchanger is connected in series with an internal channel of the first liquid-to-liquid heat exchanger to form an internal circulation loop, and the first electric valve is connected in series with the internal circulation loop. An external channel of the first liquid-to-liquid heat exchanger is connected in series with a first external cold source device to form an external circulation loop. When the dehumidification unit is in operation, air sequentially exchanges heat through the heat exchange unit and the first gas-to-liquid heat exchanger to condense water vapor in the air.

In an embodiment of the present disclosure, the refrigeration air wall apparatus also includes a humidification unit, which is configured to humidify the air.

In an embodiment of the present disclosure, the humidification unit is positioned in front of the fan unit along the air flow direction.

In an embodiment of the present disclosure, the humidification unit is at least one of an electric humidifier, a wet film humidifier, and a steam humidifier.

In an embodiment of the present disclosure, the refrigeration air wall apparatus also includes a filter unit. The heat exchange unit is positioned in front of the filter unit along the air flow direction, and the filter unit is configured to filter the air.

In an embodiment of the present disclosure, the heat exchange unit, the dehumidification unit, the fan unit, the humidification unit, and the filter unit are arranged along a rectilinear direction.

In another aspect, the present disclosure also provides a data center having a refrigeration space and an equipment rooms. The refrigeration space is provided with the refrigeration air wall apparatus. One end of the refrigeration space is interconnected to the equipment room through a return air inlet, other end of the refrigeration space is interconnected to the equipment room through an air supply outlet, and the humidification unit is positioned between the air supply outlet and the fan unit.

In an embodiment of the present disclosure, a first temperature and humidity sensor is installed at the return air inlet, and a second temperature and humidity sensor is installed at the air supply outlet. The data center enables the humidification unit based on a humidity value detected by the first temperature and humidity sensor, the data center enables the dehumidification unit based on a humidity value detected by the first temperature and humidity sensor, and the humidification unit and the dehumidification unit are not enabled simultaneously.

In an embodiment of the present disclosure, a fan speed of the fan unit and/or the heat exchange unit are regulated based on a PID control method.

Beneficial effects of the present disclosure are as below. Unlike the prior art, the present disclosure provides a refrigeration air wall apparatus. The refrigeration air wall apparatus includes a heat exchange unit, a dehumidification unit, and a fan unit, where the dehumidification unit is integrated into the refrigeration air wall apparatus. When the refrigeration air wall apparatus is used in the data center, the dehumidification unit and the refrigeration air wall apparatus are installed together in the refrigeration space, which can, compared with the prior art where dehumidifiers are provided separately in the equipment room, reduce number of systems in the data center, simplify the system architecture, facilitate subsequent on-site construction, and reduce costs.

Moreover, the dehumidification unit includes a first gas-to-liquid heat exchanger, a first liquid-to-liquid heat exchanger, and a first electric valve. The first gas-to-liquid heat exchanger exchanges heat with the external circulation loop through the first liquid-to-liquid heat exchanger to further cool the water vapor in the air, such that temperature of the water vapor in the air is lower than a condensation temperature, so the water vapor is condensed to form water droplets, thereby achieving dehumidification effects. In this way, use of the first gas-to-liquid heat exchanger may facilitate stacked arrangement of the heat exchange unit and the fan unit side by side, resulting in a smaller volume of the refrigeration air wall apparatus and improving an integration level. Moreover, the present disclosure adopts condensation and dehumidification, the heat exchange unit may be employed to reduce temperature in advance, thereby reducing power consumption required for the dehumidification unit to cool the water vapor in the air to the condensation temperature.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a refrigeration air wall apparatus according to an embodiment of the present disclosure;

FIG. 2 is a schematic structural diagram of a dehumidification unit according to an embodiment of the present disclosure; and

FIG. 3 is a schematic structural diagram of a data center according to an embodiment of the present disclosure.

Reference numerals in the accompanying drawings:

refrigeration air wall apparatus A; heat exchange unit 1; dehumidification unit 2; first gas-to-liquid heat exchanger 21; first liquid-to-liquid heat exchanger 22; first electric valve 23; fan unit 3; humidification unit 4; filter unit 5; refrigeration space 61; equipment room 62; return air inlet 63; air supply outlet 64; first temperature and humidity sensor 65; and second temperature and humidity sensor 66.

### DETAILED DESCRIPTION

Detailed description of the embodiments of the present disclosure will further be made below with reference to the accompanying drawings to make the above objectives, technical solutions and advantages of the present disclosure more apparent. Terms such as “upper” , “above” , “lower” , “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

The present disclosure provides a refrigeration air wall apparatus and a data center, which are described in detail below. It is to be noted that the description order of the following embodiments does not limit the preferred order of the embodiments in the present disclosure. In the following embodiments, description of various embodiments may be focused on differentially, and reference may be made to related descriptions of other embodiments for a part not expatiated in a certain embodiment.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

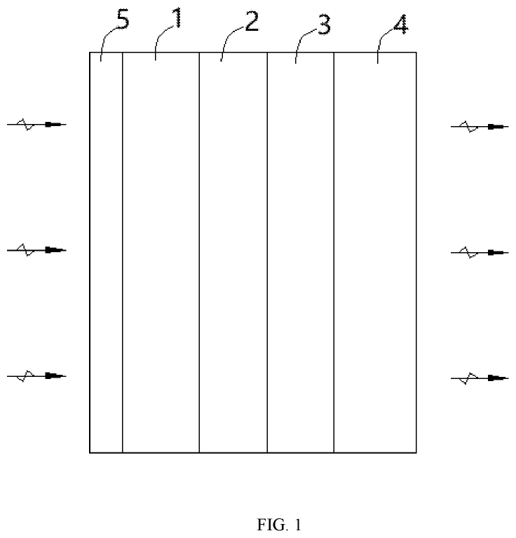

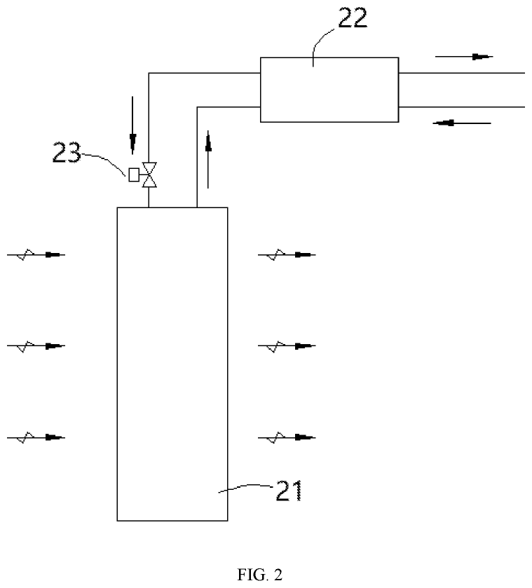

Referring to FIG. 1 and FIG. 2, FIG. 1 is a schematic structural diagram of a refrigeration air wall apparatus according to an embodiment of the present disclosure, and FIG. 2 is a schematic structural diagram of a dehumidification unit according to an embodiment of the present disclosure.

In one embodiment, the refrigeration air wall apparatus A may be installed in a data center to serve as a heat exchange device configured to exchange heat of a server device in the data center.

The refrigeration air wall apparatus A may also be independent of the data center, and the refrigeration air wall apparatus A can serve as one integral system separately. Specifically, the refrigeration air wall apparatus A may at least include a heat exchange unit 1, a dehumidification unit 2, and a fan unit 3. The dehumidification unit 2 is positioned between the heat exchange unit 1 and the fan unit 3 along an air flow direction, and the dehumidification unit 2 is positioned in front of the heat exchange unit 1. That is, the air first flows through the heat exchange unit 1 to undergo heat exchange cooling, then flows through the dehumidification unit 2 to undergo dehumidification, and then flows through the fan unit 3. The fan unit 3 is configured to overcome resistances of various functional units and provide power such that the air moves from one side of the heat exchange unit 1 to one side of the fan unit 3.

In an embodiment, the dehumidification unit 2 includes a first gas-to-liquid heat exchanger 21, a first liquid-to-liquid heat exchanger 22, and a first electric valve 23. The first gas-to-liquid heat exchanger 21 is connected in series with an internal channel of the first liquid-to-liquid heat exchanger 22 to form an internal circulation loop, where the first electric valve 23 is connected in series with the internal circulation loop, and the first electric valve 23 is configured to control ON or OFF of the dehumidification unit 2. An external channel of the first liquid-to-liquid heat exchanger 22 is connected in series with a first external cold source device to form an external circulation loop. When the dehumidification unit 2 is in operation, the air sequentially exchanges heat through the heat exchange unit 1 and the first gas-to-liquid heat exchanger 21 to condense water vapor in the air.

In this embodiment, the heat exchange unit 1 may be a gas-to-gas heat exchanger, a second gas-to-liquid heat exchanger, or a combination of both. When the heat exchange unit 1 is the gas-to-gas heat exchanger such as a heat exchange core, the gas-to-gas heat exchanger may exchange heat with air to be cooled by means of air in external environment, thereby achieving refrigeration of the air to be cooled. When the heat exchange unit 1 is the second gas-to-liquid heat exchanger, the air flows through the second gas-to-liquid heat exchanger and the first gas-to-liquid heat exchanger to exchange heat to achieve heat exchange and refrigeration. Reference may be made to the prior art for specific structures of the first gas-to-liquid heat exchanger 21, of the first liquid-to-liquid heat exchanger 22, of the gas-to-gas heat exchanger, and of the second gas-to-liquid heat exchanger, which are not to be described in detail here.

It is to be particularly pointed out that the dehumidification unit 2 is arranged between the heat exchange unit 1 and the fan unit 3. In one aspect, the dehumidification unit 2 can dehumidify the air, and then the air flows through the fan unit 3, to reduce content of the water vapor in the air in contact with the fan unit 3, thereby reducing occurrence of corrosion of the fan unit 3, and prolonging service life of the fan unit 3. In another aspect, the dehumidification unit 2 interacts with the heat exchange unit 1, and the dehumidification unit 2 cools the water vapor in the air in advance by means of the heat exchange unit 1, thereby reducing the power consumption required for the dehumidification unit 2 to cool the water vapor in the air to the condensation temperature.

It is to be noted that in this embodiment, the dehumidification unit 2 is integrated into the refrigeration air wall apparatus A. When the refrigeration air wall apparatus A is used in the data center, the dehumidification unit 2 and the refrigeration air wall apparatus A are installed together in the refrigeration space, which can, compared with the prior art where dehumidifiers are provided separately in the equipment room, reduce number of systems in the data center, simplify the system architecture, facilitate subsequent on-site construction, and reduce costs.

Moreover, the dehumidification unit 2 includes a first gas-to-liquid heat exchanger 21, a first liquid-to-liquid heat exchanger 22, and a first electric valve 23. The first gas-to-liquid heat exchanger 21 exchanges heat with the external circulation loop through the first liquid-to-liquid heat exchanger 22 to further cool the water vapor in the air, such that temperature of the water vapor in the air is lower than the condensation temperature, so the water vapor is condensed to form water droplets, thereby achieving dehumidification effects. In this way, the use of the first gas-to-liquid heat exchanger 21 may facilitate stacked arrangement of the heat exchange unit 1 and the fan unit 3 side by side, resulting in a smaller volume of the refrigeration air wall apparatus A and improving an integration level.

In one embodiment, the refrigeration air wall apparatus A also includes a humidification unit 4, which is configured to humidify the air to achieve a humidification function. Along the air flow direction, the humidification unit 4 is positioned in front of the fan unit 3.

Through the above structure, the humidification function of the refrigeration air wall apparatus A can be enhanced. Moreover, the humidification unit 4 is integrated into the refrigeration air wall apparatus A, which is different from the prior art where the dehumidifiers are installed separately in the equipment room. This embodiment can simplify the system structure, reduce space occupation of the equipment room, and improve capacity of cabinets placed in the equipment room.

Alternatively, the humidification unit 4 is at least one of an electric humidifier, a wet film humidifier, and a steam humidifier.

Further, the refrigeration air wall apparatus A may also include a filter unit 5. The heat exchange unit 1 is positioned in front of the filter unit 5 along the air flow direction, and the filter unit 5 is configured to filter the air entering the refrigeration air wall apparatus A to protect the functional units inside the refrigeration air wall apparatus A.

Further, the heat exchange unit 1, the dehumidification unit 2, the fan unit 3, the humidification unit 4, and the filter unit 5 are arranged along a rectilinear direction. Of course, considering that different application scenes have different layouts in practical use, the heat exchange unit 1, the dehumidification unit 2, the fan unit 3, the humidification unit 4, and the filter unit 5 may also be arranged in a curve or arbitrary shape according to the actual scene layout.

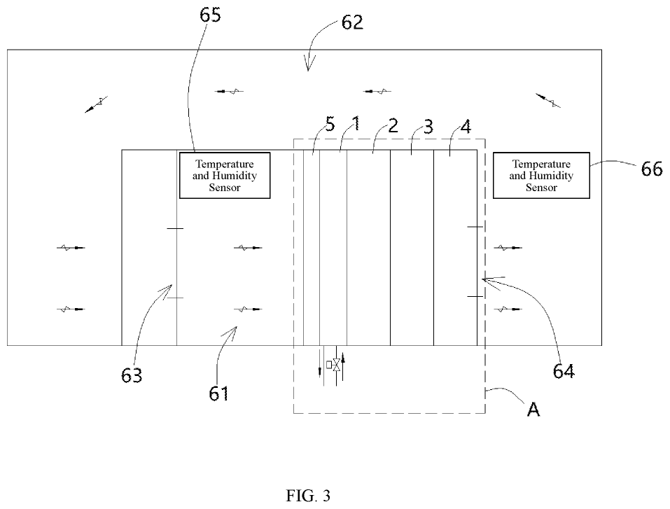

Referring to FIG. 3, FIG. 3 is a schematic structural diagram of a data center according to an embodiment of the present disclosure.

Correspondingly, the present disclosure also provides a data center having a refrigeration space 61 and an equipment room 62. The refrigeration space 61 is provided with the refrigeration air wall apparatus A, and the equipment room 62 is provided with server devices, power distribution devices, etc. One end of the refrigeration space 61 is interconnected to the equipment room 62 through a return air inlet 63, and other end of the refrigeration space 61 is interconnected to the equipment room 62 through an air supply outlet 64. In this way, a circulating air flow may be formed between the refrigeration space 61 and the equipment room 62. That is, the air can enter the refrigeration space 61 from the equipment room 62 through the return air inlet 63, and then enter the equipment room 62 from the refrigeration space 61 through the air supply outlet 64, and cycle back and forth in sequence. The humidification unit 4 is positioned between the air supply outlet 64 and the fan unit 3.

In this embodiment, when the air flows through the equipment room 62, the air exchanges heat with devices in the equipment room 62 and rises in temperature. Next, the heated air enters the refrigeration space 61 and passes through the functional units of the refrigeration air wall apparatus A in sequence to achieve one or more functions of filtration, heat exchange cooling, dehumidification, and humidification.

In an embodiment, a first temperature and humidity sensor 65 is installed at the return air inlet 63, and a second temperature and humidity sensor 66 is installed at the air supply outlet 64. A control module of the data center may enable the humidification unit 4 based on a humidity value detected by the first temperature and humidity sensor 65, the control module of the data center may enable the dehumidification unit 2 based on a humidity value detected by the first temperature and humidity sensor 65. It is to be noted that the humidification unit 4 and the dehumidification unit 2 cannot be enabled simultaneously.

In practical applications, a first set value and a second set value may be preset for the control module of the data center, and the first set value is less than the second set value. When the humidity value detected by the first temperature and humidity sensor 65 is less than the first set value, the humidification unit 4 is enabled for humidification; otherwise the humidification unit 4 is turned off. When the humidity value detected by the second temperature and humidity sensor 66 is greater than the second set value, the dehumidification unit 2 is enabled by turning on the first electric valve 23; otherwise the humidification unit 4 is turned off. Of course, the first set value may also be set to be equal to the second set value, which is not limited in the present disclosure.

In one embodiment, a fan speed of the fan unit 3 and/or the heat exchange unit 1 are regulated based on a PID control method.

The control module may separately collect temperature values collected by the first temperature and humidity sensor 65 and the second temperature and humidity sensor 66, and may control the fan speed of the fan unit 3 and/or a rotational speed of a water pump or a rotate speed of a fan in the heat exchange unit 1 based on the PID control method, to meet refrigeration demands of the equipment room 62.

As can be seen from the technical solutions adopted in the present disclosure, the refrigeration air wall apparatus includes a heat exchange unit, a dehumidification unit and a fan unit, where the dehumidification unit is integrated into the refrigeration air wall apparatus. When the refrigeration air wall apparatus is used in the data center, the dehumidification unit and the refrigeration air wall apparatus are installed together in the refrigeration space, so the dehumidifiers are not required to be provided separately in the equipment room, which can reduce number of systems in the data center, simplify the system architecture, facilitate subsequent on-site construction, and reduce costs.

Moreover, the dehumidification unit includes a first gas-to-liquid heat exchanger, a first liquid-to-liquid heat exchanger, and a first electric valve. The first gas-to-liquid heat exchanger exchanges heat with the external circulation loop through the first liquid-to-liquid heat exchanger to further cool the water vapor in the air, such that the temperature of the water vapor in the air is lower than the condensation temperature, so the water vapor is condensed to form the water droplets, thereby achieving the dehumidification effects. In this way, use of the first gas-to-liquid heat exchanger may facilitate stacked arrangement of the heat exchange unit and the fan unit side by side, resulting in a smaller volume of the refrigeration air wall apparatus and improving the integration level.

Further, the dehumidification unit is arranged between the heat exchange unit and the fan unit. In one aspect, the dehumidification unit can dehumidify the air, and then the air flows through the fan unit, to reduce content of the water vapor in the air in contact with the fan unit, thereby reducing occurrence of corrosion of the fan unit, and prolonging the service life of the fan unit. In another aspect, the dehumidification unit interacts with the heat exchange unit, and the dehumidification unit cools the water vapor in the air in advance by means of the heat exchange unit, thereby reducing the power consumption required for the dehumidification unit to cool the water vapor in the air to the condensation temperature.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A refrigeration air wall apparatus at least comprising a heat exchange unit, a dehumidification unit, and a fan unit, wherein the dehumidification unit is positioned between the heat exchange unit and the fan unit along an air flow direction, and the dehumidification unit is positioned in front of the heat exchange unit;
the dehumidification unit comprises a first gas-to-liquid heat exchanger, a first liquid-to-liquid heat exchanger, and a first electric valve;
the first gas-to-liquid heat exchanger is connected in series with an internal channel of the first liquid-to-liquid heat exchanger to form an internal circulation loop, the first electric valve being connected in series with the internal circulation loop;
an external channel of the first liquid-to-liquid heat exchanger is connected in series with a first external cold source device to form an external circulation loop; and
when the dehumidification unit is in operation, air sequentially exchanges heat through the heat exchange unit and the first gas-to-liquid heat exchanger to condense water vapor in the air.

2. The refrigeration air wall apparatus according to claim 1 further comprising a humidification unit configured to humidify the air.

3. The refrigeration air wall apparatus according to claim 2, wherein the humidification unit is positioned in front of the fan unit along the air flow direction.

4. The refrigeration air wall apparatus according to claim 3, wherein the humidification unit is at least one of an electric humidifier, a wet film humidifier, and a steam humidifier.

5. The refrigeration air wall apparatus according to claim 4 further comprising a filter unit; wherein
the heat exchange unit is positioned in front of the filter unit along the air flow direction, and the filter unit is configured to filter the air.

6. The refrigeration air wall apparatus according to claim 5, wherein the heat exchange unit, the dehumidification unit, the fan unit, the humidification unit, and the filter unit are arranged along a rectilinear direction.

7. A data center having a refrigeration space and an equipment room; wherein
the refrigeration space is provided with a refrigeration air wall apparatus; and
one end of the refrigeration space is interconnected to the equipment room through a return air inlet, and other end of the refrigeration space is interconnected to the equipment room through an air supply outlet, the humidification unit being positioned between the air supply outlet and the fan unit.

8. The data center according to claim 7, wherein a first temperature and humidity sensor is installed at the return air inlet, and a second temperature and humidity sensor is installed at the air supply outlet; and
the data center enables the humidification unit based on a humidity value detected by the first temperature and humidity sensor, the data center enables the dehumidification unit based on a humidity value detected by the first temperature and humidity sensor, and the humidification unit and the dehumidification unit are not enabled simultaneously.

9. The data center according to claim 8, wherein a fan speed of the fan unit and/or the heat exchange unit are regulated based on a PID control method.

10. The data center according to claim 7 further comprising a humidification unit configured to humidify the air.

11. The data center according to claim 10, wherein the humidification unit is positioned in front of the fan unit along the air flow direction.

12. The data center according to claim 11, wherein the humidification unit is at least one of an electric humidifier, a wet film humidifier, and a steam humidifier.

13. The data center according to claim 12 further comprising a filter unit; wherein the heat exchange unit is positioned in front of the filter unit along the air flow direction, and the filter unit is configured to filter the air.

14. The data center according to claim 13, wherein the heat exchange unit, the dehumidification unit, the fan unit, the humidification unit, and the filter unit are arranged along a rectilinear direction.
